(19) United States
(12) Patent Application Publication
(10) Pub. No.: US 2026/0352178 A1
(43) Pub. Date: Nov. 5, 2026

(54) CONTROL OF THE TEMPERATURE COEFFICIENT OF FREQUENCY OF A MICROELECTROMECHANICAL SYSTEMS (MEMS) RESONATOR VIA MANIPULATION BY STRESS

(71) Applicant: Georgia Tech Research Corporation, Atlanta, GA (US)

(72) Inventors: Yaoyao Long, Atlanta, GA (US); Farrokh Ayazi, Atlanta, GA (US); Zhenming Liu, Atlanta, GA (US)

(21) Appl. No.: 19/486,222

(22) PCT Filed: May 26, 2024
(86) PCT No.: PCT/US2024/031185

§ 371 Date: Nov. 20, 2025

Related U.S. Application Data
(60) Provisional application No. 63/504,642, filed on May 26, 2023.

(51) Int. Cl. H03H 9/02; H03H 3/007

(52) U.S. Cl. CPC H03H 9/02448; H03H 3/0076

(57) ABSTRACT

An exemplary embodiment provides a micro-electromechanical resonator having a positive temperature coefficient of frequency (TCP). Another embodiment provides a method of manufacturing a desired micro-electromechanical resonator, comprising: determining a desired property for the resonator over a predetermined temperature range; selecting one or more dimensions and/or one or more materials of the resonator based on the desired TCP; and providing the resonator with the one or more dimensions and/or one or more materials, in which the desired property can be one or more properties selected from the group consisting of: a temperature coefficient of frequency (TCP); a temperature turnover point; and a frequency shift.

### CROSS-REFERENCE TO RELATED APPLICATIONS

This application is a §371 National Stage of International Patent Application No. PCT/US2024/031185, with an international filing date of 26 May 2024, which International Patent Application No. PCT/US2024/031185 claims the benefit of US. Provisional Application No. 63/504,642, filed 26 May 2023, each of which is incorporated herein by reference in its entirety as if fully set forth below.

### FIELD OF THE DISCLOSURE

The present invention relates to the field of microelectromechanical systems (MEMS), and more particularly to temperature compensated MEMS resonators and a temperature stable MEMS resonator, and more specifically to systems and methods to control the temperature coefficient of frequency (TCF) of a MEMS resonator.

### BACKGROUND

Precision time and frequency references are integral to the foundational operations of modern society and its technological infrastructure. Timing references play a critical role in areas ranging from quantum mechanics to global positioning systems, telecommunications, and network synchronization in sectors such as aerospace, consumer electronics, and healthcare for accurate transaction timestamps. The necessity for precision in timekeeping is not just an academic endeavor but also a practical one, underpinning the efficiency and reliability of systems across various industries.

Historically, quartz crystal has been the linchpin for modern frequency reference technologies, owing to its exceptional frequency stability over a wide temperature range. However, micro-electromechanical resonators (i.e. MEMS resonators) are poised as potential successors to quartz reference oscillators, especially in applications like wireless communication and wearable electronics. MEMS resonators have the potential to reduce size and drive down manufacturing costs through integration with CMOS processes. Nevertheless, MEMS resonators are often beleaguered by large frequency shifts due to changes in ambient temperature.

The temperature stability of a resonator is gauged by two primary metrics: the overall frequency shift over a temperature range and the temperature coefficient of frequency or TCF. The former denotes the net frequency drift over a defined temperature interval and acts as a holistic measure of thermal stability, particularly in non-oven-controlled oscillators. The TCF on the other hand quantifies the rate of frequency variation as temperature varies. Given that temperature-dependency of frequency encompasses an amalgamation of both linear and higher-order polynomial components, TCF₁ represents the linear deviated frequency change and TCF₂ indicates the second-order deviation, as shown by the equation below:

$${TCF}_{1} = \frac{1}{{f}_{ref}} \frac{\partial f}{\partial T} ; {TCF}_{2} = \frac{{TCF}_{1}}{{f}_{ref}} \frac{\partial f}{\partial T} \qquad Equation l$$

Attaining a near-zero TCF₁ can be essential for bolstering timekeeping accuracy. The temperature turnover point of TCF, where the TCF₁ is equal to zero, resulting from a transition of TCF₁ from a positive value to a negative value, can also hold paramount importance for stabilizing the frequency of the resonator through ovenization. As such, the creation and control of the TCF turn-over point can be vital for applications like oven-controlled oscillators.

To counteract the material softening effects induced by temperature and attain zero TCF₁, a variety of conventional temperature compensation strategies—both passive and active—have been employed. Passive methods encompass the utilization of composite materials, high doping concentration, and engineered stress profiles, offering the advantage of not necessitating external power sources. Conversely, active compensation techniques, such as electrostatic modulation, phase-locked loops (PLLs), and oven control, typically require external power supplies for operation. Notably, the application of longitudinal tensile stress emerges as a low-power and cost-effective solution that obviates the need for high doping concentrations or the synthesis of composite materials. Moreover, as we introduce stress, the stress term in TCF can be used to customize thermal stability, including TCF and overall frequency shift. This adaptability provides a framework for devising customized solutions that are attuned to the specific application environments. Previous research explored stress compensation in Si-based MEMS resonators, leveraging epoxy or aluminum (Al) layers to modulate stress induced by the Coefficient of Thermal Expansion (CTE) mismatch. Yet, these undertakings grappled with challenges such as pronounced frequency shifts (evidently absent from any empirical zero TCF₁ results), temperature-dependent frequency hysteresis, suboptimal yield rates, and unpredictable stability.

Accordingly, there is a need for improved resonators and methods of making the same that overcome one or more of the deficiencies with conventional devices discussed above.

### BRIEF SUMMARY

An exemplary embodiment of the present disclosure provides a micro-electromechanical resonator having a positive temperature coefficient of frequency (TCF).

In any of the embodiments disclosed herein, the vibrations of the resonator can be actuated and sensed using capacitive transducers separated from the resonator body by airgaps.

In any of the embodiments disclosed herein, the resonator can have a positive TCF over a temperature range of from 200K to about 500K.

In any of the embodiments disclosed herein, the resonator can have one or more dimensions selected to achieve the positive TCF.

In any of the embodiments disclosed herein, the one or more dimensions can be selected from the group consisting of: a length of the resonator, a width of the resonator, an aspect ratio of the resonator, a thickness of the resonator, a radius of the resonator, a length of one or more anchors, a width of one or more anchors, an aspect ratio of one or more anchors, and a thickness of one or more anchors.

In any of the embodiments disclosed herein, the resonator can be disposed on a substrate, the substrate having a different coefficient of thermal expansion than the resonator.

In any of the embodiments disclosed herein, the resonator can comprise silicon carbide and the substate can comprise silicon.

In any of the embodiments disclosed herein, the resonator can be bonded to the substrate via a silicon dioxide layer.

In any of the embodiments disclosed herein, the resonator can be disposed between two anchors on opposing ends of the resonator.

In any of the embodiments disclosed herein, the resonator can be one of a beam resonator, a ring resonator, a frame resonator, a rectangular resonator, a flexural mode resonator, a torsional resonator, and an extensional mode resonator.

In any of the embodiments disclosed herein, the resonator can have a temperature turnover point of between 200K and 500K.

Another embodiment of the present disclosure provides a method of manufacturing a desired micro-electromechanical resonator, comprising: determining a desired property for the resonator over a predetermined temperature range; selecting one or more dimensions and/or one or more materials of the resonator based on the desired property; and providing the resonator with the one or more dimensions and/or one or more materials, in which the desired property can be one or more properties selected from the group consisting of: a temperature coefficient of frequency (TCF); a temperature turnover point; and a frequency shift.

In any of the embodiments disclosed herein, the desired property can be a TCF, and the TCF can comprise a range of desired TCFs for the resonator over the predetermined temperature range.

In any of the embodiments disclosed herein, the desired property can be a TCF with a positive value.

In any of the embodiments disclosed herein, the temperature range cam be from about 200K to about 500K.

In any of the embodiments disclosed herein, the method can further comprise inducing axial stress in the resonator by leveraging a coefficient of thermal expansion (CTE) mismatch between a material of the resonator and at least one layer positioned beneath the resonator.

In any of the embodiments disclosed herein, the material of the resonator can comprise silicon carbide and the at least one layer positioned beneath the resonator can comprise silicon.

In any of the embodiments disclosed herein, the silicon carbide resonator cam be bonded to the at least one silicon layer positioned beneath the resonator via a silicon dioxide layer.

In any of the embodiments disclosed herein, the method can further comprise determining a desired temperature turnover point for the resonator, and the one or more dimensions of the resonator can be further selected based on the desired temperature turnover point.

These and other aspects of the present disclosure are described in the Detailed Description below and the accompanying drawings. Other aspects and features of embodiments will become apparent to those of ordinary skill in the art upon reviewing the following description of specific, exemplary embodiments in concert with the drawings. While features of the present disclosure may be discussed relative to certain embodiments and figures, all embodiments of the present disclosure can include one or more of the features discussed herein. Further, while one or more embodiments may be discussed as having certain advantageous features, one or more of such features may also be used with the various embodiments discussed herein. In similar fashion, while exemplary embodiments may be discussed below as device, system, or method embodiments, it is to be understood that such exemplary embodiments can be implemented in various devices, systems, and methods of the present disclosure.

### BRIEF DESCRIPTION OF THE DRAWINGS

The following detailed description of specific embodiments of the disclosure will be better understood when read in conjunction with the appended drawings. For the purpose of illustrating the disclosure, specific embodiments are shown in the drawings. It should be understood, however, that the disclosure is not limited to the precise arrangements and instrumentalities of the embodiments shown in the drawings.

FIG. 1A provides a top view SEM image of a fabricated 4H—SiC DC flexure mode beam microresonator and the smooth sidewall of the trench, in which with CTE-induced axial stress, the longitudinal length of the beam was elongated from designed 1100 μm to 1101.3 μm. FIG. 1B provides a cross-sectional schematic view of an exemplary 1100 μm×37 μm resonator along with the simulated mode shape of the resonator at 368 kHz. FIG. 1C provides a plot of room temperature frequency response of the exemplary 1100 μm×17 μm beam resonator, with CTE-induced axial stress bringing frequency from 178 kHz to 226 kHz. FIG. 1D provides a plot of the numerical solution and linear approximation of the mode constant (β)'s dependence on axial stress (σ), which demonstrates the nonlinear relationship between β and σ, with a convergence to 10-8 under an axial stress of approximately 300 MPa, leading to a ξσ convergence near 3. Around this point (ξσ=3), the stress shift can be linearly approximated, facilitating the simplification of the equation's inaugural component to a scalar value of 0.066, modulated by ξ and its temperature-driven stress deviation.

FIG. 2A illustrates two predominant constituents of the thermal stress in a resonator system. FIG. 2B illustrates COMSOL simulated CTE-mismatch-introduced stress in an exemplary 4H—SiCOI system. FIG. 2C provides a plot of simulated anchor-introduced compressive axial stress. FIG. 2D provides a plot of CTE-mismatch-introduced tensile axial stress (bottom right) in 1100 μm long beam resonators (17-55 μm wide) on 4H—SiCOI substrate, which illustrates that narrower beams with a higher (L/W) ratio exhibit higher net axial stress and factor of the stress change rates (ξ), and, for narrower beams, CTE mismatch-induced stress more significantly dominates total axial stress.

FIGS. 3A-D provides plots showing temperature dependent (FIG. 3A) TCE and (FIG. 3B) CTE of 4H—SiC can be linearly fitted. FIG. 3C provides a plot of temperature response and (FIG. 3D) TCF₁ of 1100 μm long resonators, ranging in width from 17 to 55 μm, across −25 to 110 °C, in which the simulated and empirical TCF turnover points and TCF₂ values are detailed in the tables, and the high degree of congruence between the simulated and measured temperature response values is substantiated by adjusted R² values, shown in the table (Note the TCF turnover point of 55 μm wide resonator is the estimated value).

FIG. 4 provides a plot showing the temperature response of quality factor with 1100 μm long resonators, ranging in width from 17 to 55 μm, across −25 to 110 °C, showing that, for resonators with widths ranging from 17 to 27 μm, the quality factor diminishes with increasing temperature, primarily influenced by TED, for the width at 37 μm, the quality factor only has a slight variation in the temperature range, evenly manipulated by TED and anchor loss, but resonators with a width of 55 μm exhibit an increasing quality factor with temperature, predominantly governed by anchor loss.

FIGS. 5A-B provides plots that show, with an 1100 μm×37 μm beam resonator, (FIG. 5A) the frequency response over a temperature cycle from 25 °C to 85 °C then back to 25 °C in the vacuum chamber, with 2-hour measurements at each measured temperature point, and (FIG. 5B) the Allan deviation measurements of the resonator at room temperature and its local zero TCF point (55 °C).

FIGS. 6A-C show long-term stability of 1100 μm long DC beam resonators with widths of 17 μm, 27 μm, and 37 μm measured in a vacuum chamber over 35 days, with 50 data points collected per day. The standard deviation (σ) for each day's data is less than 0.1 ppm. Resonators with these dimensions were aged at a pre-aged temperature of 100 °C on the same die, with frequency shifts shown in (FIG. 6A) and quality factor changes in (FIG. 6C). In (FIG. 6B), frequency shifts of resonators with the same dimensions were aged at their local zero TCF points (100 °C, 85 °C, and 55 °C) on different dies.

FIG. 7A-E illustrate an exemplary 4H—SiCOI substrate's low-temperature wafer-level fabrication process. FIG. 7A shows in-situ doped polysilicon forms electrode pads on the SiC surface. FIG. 7B shows a Cr/Au seed layer is used to create an electroplated Ni-hard mask for 4H—SiC DRIE. FIG. 7C shows the wafer undergoes PECVD SiO2 patterning followed by standard Bosch-process etching in the Si handle layer. FIG. 7D shows die-level annealing at 1,100 °C is performed for oxide densification and the formation of ohmic contacts between polysilicon and SiC. FIG. 7E shows the final cross-sectional view of fabricated 4H—SiCOI substrate.

FIG. 8 provides a flow chart of a method of manufacturing a desired micro-electromechanical resonator, in accordance with some embodiments of the present disclosure.

### DETAILED DESCRIPTION

To facilitate an understanding of the principles and features of the various embodiments of the invention, various illustrative embodiments are explained below. Although exemplary embodiments of the invention are explained in detail, it is to be understood that other embodiments are contemplated. Accordingly, it is not intended that the invention is limited in its scope to the details of construction and arrangement of components set forth in the following description or illustrated in the drawings. The invention is capable of other embodiments and of being practiced or carried out in various ways. Also, in describing the exemplary embodiments, specific terminology will be resorted to for the sake of clarity.

It must also be noted that, as used in the specification and the appended claims, the singular forms “a,” “an” and “the” include plural references unless the context clearly dictates otherwise. For example, reference to a component is intended also to include composition of a plurality of components. References to a composition containing “a” constituent is intended to include other constituents in addition to the one named.

Also, in describing the exemplary embodiments, terminology will be resorted to for the sake of clarity. It is intended that each term contemplates its broadest meaning as understood by those skilled in the art and includes all technical equivalents which operate in a similar manner to accomplish a similar purpose.

Ranges may be expressed herein as from “about” or “approximately” or “substantially” one particular value and/or to “about” or “approximately” or “substantially” another particular value. When such a range is expressed, other exemplary embodiments include from the one particular value and/or to the other particular value.

Similarly, as used herein, “substantially free” of something, or “substantially pure”, and like characterizations, can include both being “at least substantially free” of something, or “at least substantially pure”, and being “completely free” of something, or “completely pure”.

By “comprising” or “containing” or “including” is meant that at least the named compound, element, particle, or method step is present in the composition or article or method, but does not exclude the presence of other compounds, materials, particles, method steps, even if the other such compounds, material, particles, method steps have the same function as what is named.

It is also to be understood that the mention of one or more method steps does not preclude the presence of additional method steps or intervening method steps between those steps expressly identified. Similarly, it is also to be understood that the mention of one or more components in a composition does not preclude the presence of additional components than those expressly identified.

The materials described as making up the various elements of the invention are intended to be illustrative and not restrictive. Many suitable materials that would perform the same or a similar function as the materials described herein are intended to be embraced within the scope of the invention. Such other materials not described herein can include, but are not limited to, for example, materials that are developed after the time of the development of the invention.

By contrast to the conventional technologies discussed above, some of the approaches disclosed herein can harness the unique properties of resonator materials like 4H—SiC, which has emerged as a vanguard material for MEMS owing to its distinct mechanical and thermal attributes. In this case, especially, 4H—SiC has a Temperature Coefficient of Young's Modulus (TCE) half that of Si and a CTE twice as large. This can enhance the efficacy of stress compensation, leading to a near-zero TCF₁ with minimal frequency fluctuation. In particular, embodiments disclosed herein, benefit from the new discovery that the tensile stress arising from CTE incongruities between materials of the resonator and substrate layer(s) can be closely tied to the geometrical dimensions of the resonator (and/or anchors). Thus, controlling these dimensions can allow a designer to realize improved TCF performance in resonators. Furthermore, the 4H—SiC resonators disclosed herein, which can be built upon the 4H—SiCOI substrate, can benefit from the inherent strong interlayer bonds, which can not only eradicate frequency hysteresis but can also augment the yield rate and assure stability metrics.

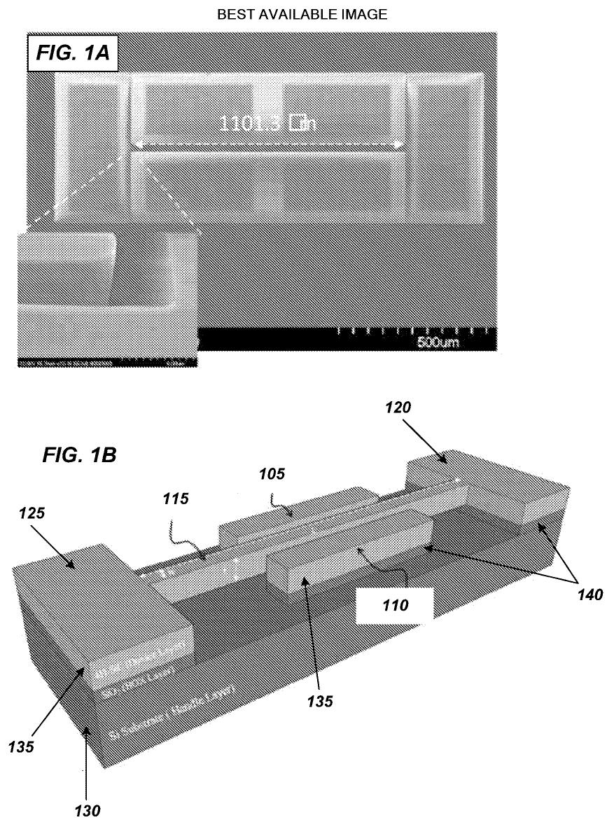

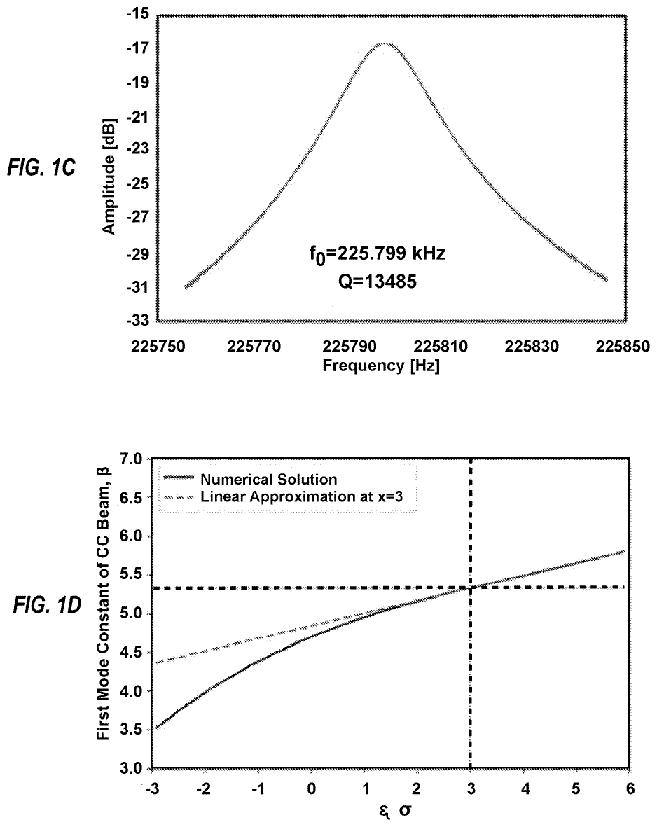

FIG. 1B provides a schematic of an exemplary micro-electromechanical system (MEMS) resonator of the present disclosure. The resonator shown in FIG. 1B is a beam resonator, though the present disclosure is not so limited. Rather, as those skilled in the art would appreciate when reviewing the entirety of the disclosure herein, embodiments of the present disclosure can provide many other types of resonators, including, but not limited to, a ring resonator, a frame resonator, a rectangular resonator, a flexural mode resonator, a torsional resonator, an extensional mode resonator, and the like. As shown in FIG. 1B, the resonator can comprise a drive electrode 105, a sense electrode 110, and a beam 115. The resonator can further comprise one or more anchors 120 125 disposed at ends of the beam 115. The resonators of the present disclosure, however, are not limited to any number of electrodes or anchors, nor are they limited to any particular resonator shape.

The resonator can comprise multiple layers in the various components. These layers can include many different materials. As explained herein, the differences in CTE of these materials can allow for optimization of certain properties of the resonator, including, but not limited to, TCF, a temperature turnover point, and a frequency shift. In some embodiments, as shown in FIG. 1B, the resonator can include a silicon substrate 130 and a silicon carbide resonator device layer 135 (e.g., a 4H—SiC). A silicon dioxide layer 140 can be used to attach the resonator device layer 135 to the silicon substrate layer 130. A conductive layer (not shown), such as poly-silicon, can be positioned above the device layer 135 on various components, such as the electrodes 105 110 and anchors 120 125. Each of these materials, in particular the device layer 135 material and the substrate 130 material, can have varying CTEs.

As explained in more detail in the Examples section below, by varying one or more dimensions of components of the resonator, the TCF, turnover temperature point, and/or frequency shift, can be controlled. Indeed, by utilizing the methodology disclosed herein, resonators with positive TCF can be realized for the first time. In some embodiments, the dimensions can be selected to achieve a particular TCF or range of TCFs over varying temperature ranges. For example, it may be desirable to select dimensions (and/or materials) for the resonator such that the resonator maintains a positive TCF over temperature ranges for which the resonator will likely be exposed. For example, in some embodiments, the resonators can maintain a positive TCF at temperatures above 150K, 175K, 200K, 220K, 250K, 273K, 300K, 325K, 350K, 373K, 400K, 425K, 450K, 480K, or 500K. In some embodiments, the resonator can maintain a positive TCF at various ranges amongst these enumerated values, e.g., 150K-500K, 220K-373K, etc. Similarly, the resonators of the present disclosure can also be designed to have temperature turnover points at any of these enumerated values, e.g., 175K, 250K, 373K, etc., or within a range of temperatures defined by these values, e.g., 200K-500K, 250K-273K, 450K-480K, etc.

As discussed in more detail below, dimensions of the various components of the resonator can be varied to achieve a desired property. The potential dimensions which can be altered, include, but are not limited to, a length of the resonator (e.g., beam length), a width of the resonator (e.g., beam width), an aspect ratio of the resonator (beam aspect ratio), a thickness of the resonator (e.g., SiC layer 135 thickness, Si substrate layer 130 thickness, etc.), a radius of the resonator (e.g., if resonator is circular), a length of one or more anchors, a width of one or more anchors, an aspect ratio of one or more anchors, and a thickness of one or more anchors (or layers thereof).

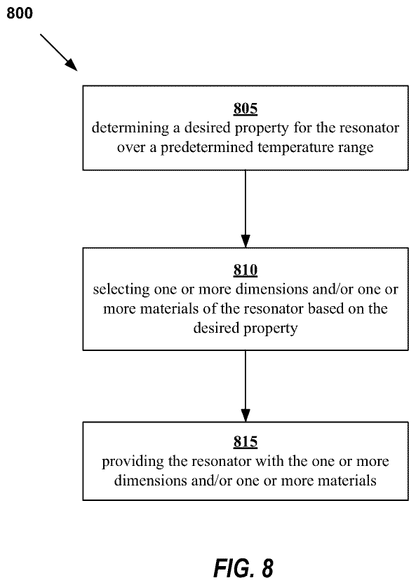

As shown in FIG. 8, another embodiment of the present disclosure provides a method 800 of manufacturing a desired micro-electromechanical resonator. The method 800 can comprise determining a desired property for the resonator over a predetermined temperature range 805. The desired property can be one or more of a TCF, a temperature turnover point, and a frequency shift. The method 800 can further comprise selecting one or more dimensions and/or one or more materials of the resonator based on the desired property 810. The method 800 can then further comprise providing the resonator with the one or more dimensions and/or one or more materials 815.

Additionally, in some embodiments, the method 800 can further comprise inducing axial stress in the resonator by leveraging a CTE mismatch between a material of the resonator and at least one layer positioned beneath the resonator.

### EXAMPLES

Below certain exemplary embodiments of the present technology are disclosed. These embodiments and the discussion of the same are included to provide examples of potential embodiments, including both resonators and methods of manufacturing such resonators. The disclosure below, however, should not be interpreted as limiting the scope of the present disclosure.

As discussed in more detail below, the customizable temperature stability analysis of an exemplary 4H—SiC doubly-clamped (DC) flexural mode beam microresonator on the 4H—SiCOI substrate is presented. The micro-electro-mechanical-systems (MEMS) resonator can be actuated and sensed capacitively. The stress source within this system is elucidated, spotlighting the key factors that shape the stress and the thermal stability properties. Furthermore, we provide detailed exemplary strategies to geometrically tailor the TCF, encompassing both its TCF₁ and TCF₂, the temperature turnover point, and the overall frequency shift of the DC beam resonator. The insights disclosed herein are not confined solely to the 4H—SiCOI platform but can be extended to other material system, underscoring the versatility of our findings. Additionally, the comprehensive evaluation of the resonator's stability across short- and long-term intervals in the 4H—SiCOI system is provided below, which will also provide an integrated assessment of an exemplary resonator's performance when utilizing the geometric design methodology in the 4H—SiCOI system.

### EXPERIMENTAL RESULTS AND DISCUSSION

FIGs. A-B present an exemplary high aspect ratio 4H—SiC DC beam resonator whose resonant frequency is derived by its motion equations' eigenvalue solutions.

$${f}_{CC - beam} = \frac{{β}_{DC}^{2} W}{4 \sqrt{3} π {L}^{2}} \sqrt{\frac{E}{ρ}} \qquad Equation 2$$

Herein, β is the modal constant with a designated value of 4.73 for the inaugural mode of an unstressed DC beam. ρ is the material density, specifically 3166 kg/m³ for 4H—SiC. W and L are the orthogonal spatial dimensions of the beam in the vibrational framework. E symbolizes Young's modulus. The temperature-modulated Young's modulus for 4H—SiC is given by Sato et al., “High-Temperature Operation of Electrostatically-Excited Single-Crystalline 4H—SiC Microcantilever Resonators,” presented at the Silicon Carbide and Related Materials 2014, 7, 2015.

$$E = {E}_{0} - {BTe}^{- \frac{{T}_{0}}{T}} \qquad Equation 3$$

With E₀—the Young's modulus at absolute zero Kelvin—equating to 449 GPa for 4H—SiC. Constants B and T₀ correspond to 0.0324 GPa/K and 640 K for 4H—SiC [32], respectively.

Based on Equation 2, the simulated resonant frequency for a DC beam measuring 17 μm×1100 μm is proximally 178 kHz at room temperature. The numerical result is significantly lower than the experimentally observed 226 kHz, as shown in FIG. 1C. When considered alongside the elongated beam length and the amplified effective stiffness, this elevated experimental resonant frequency suggests the presence of post-fabrication tensile stress within the beam, which can amplify the effective stiffness. COMSOL-based computations underscore an initial tensile strain of 297 MPa, inducing a beam elongation proximate to 1.3 μm introduced by stress (FIG. 1AError! Reference source not found.). This intrinsic stress considerations can become important factor for engineering the TCF of the 4H—SiC DC beam.

The TCF₁ of stress perturbed DC beams is derived by Equation 1 and 3.

$${TCF}_{1} = \frac{2}{β} \frac{\partial β}{\partial σ} \frac{\partial σ}{\partial T} + \frac{TCE}{2} + \frac{CTE}{2} \qquad Equation 4 A$$

To examine the thermal sensitivity of the mode constant (β), it can be imperative to analyze both the variation of β with axial stress (σ) and the subsequent alteration of σ with temperature. β's axial stress dependency can be intrinsically nonlinear, necessitating iterative numerical solutions. In this case, ξ can converge to 10⁻⁸ under an axial stress of approximately 300 MPa, leading to a ξσ convergence near 3. Under infinitesimal stress perturbations, the σ shift can be linearly approximated around ξσ=3 (FIG. 1D). As such, the equation's inaugural component can be simplified via a scalar, 0.066, modulated by ξ and its temperature-driven stress deviation (Equation 4B).

$${TCF}_{1} ≅ 0 \text{.066} ξ \frac{\partial σ}{\partial T} + \frac{TCE}{2} + \frac{CTE}{2} where \qquad Equation 4 B$$

$$ξ = \frac{12 {L}_{0}^{2}}{{π}^{2} {EW}_{0}^{2}}$$

TCE can serve as a quantitative metric for the thermal dependence of material elasticity. Based on Equation 3, the TCE of 4H—SiC can evolve as:

$$TCE = \frac{1}{{E}_{0}} \frac{\partial E}{\partial T} = - \frac{B}{{E}_{0}} ( 1 + \frac{{T}_{0}}{T} ) exp ( - \frac{{T}_{0}}{T} ) \qquad Equation 5$$

Additionally, CTE can indicate the material's thermally-induced dimensional flux.

CTE=3.21×10⁻⁶+3.56×10⁻⁹T−1.62×10⁻¹²T² Equation 6:

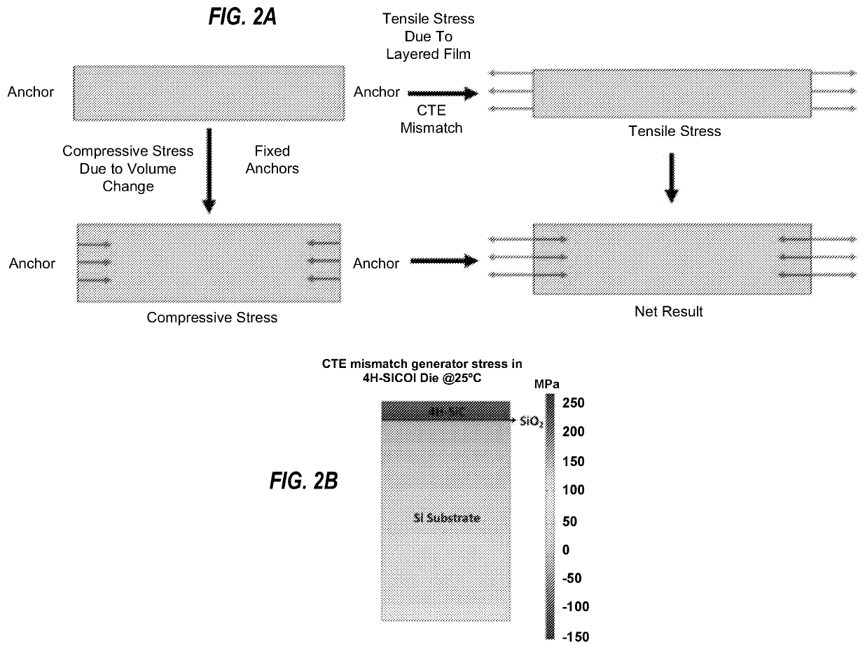

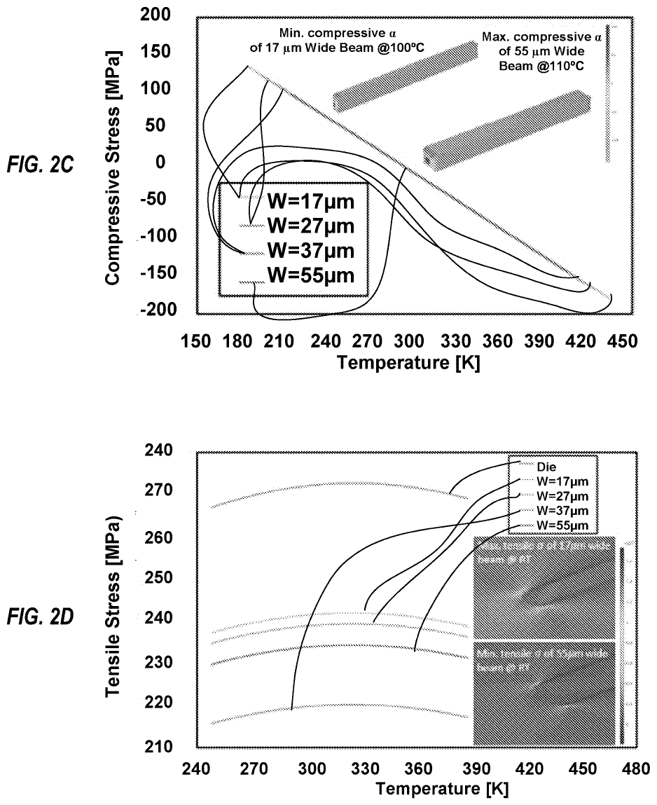

Within the examined context, the thermal stress can be primarily bifurcated into two predominant constituents, as illustrated in FIG. 2A. The primary factor can involve tensile stress arising from the CTE incongruities among Si, silicon dioxide (SiO₂), and SiC layers within the 4H—SiCOI substrate. Considering that the CTE of 4H—SiC can be approximately twice that of Si, the ensuing CTE-mismatch-induced stress within the 4H—SiCOI system can significantly surpass that in the SOI system. This discrepancy can enhance the scope for modulating stress design with 4H—SiCOI substrates. Following the deposition of 4H—SiC at 700 °C (973 K), the device layer can exhibit a tensile stress of approximately 250 MPa at room temperature (FIG. 2B). Although the die can undergo an annealing process at 1100 °C, the intrinsic thermal robustness of the SiC crystal structure can benefit from an annealing temperature of approximately 1800 °C for effective thermal stress reduction. The tensile stress induced by the CTE incongruities can be fitted by second-degree polynomial equations, as illustrated in FIG. 2D. A narrower DC beam, which proportionally decreased the area of the empty BOX layer below the beam resonator, results in elevated tensile stress levels and accelerated stress change rates. These findings are be corroborated by the simulated data presented in FIG. 2D. The results indicate that the tensile stress arising from CTE incongruities can be closely tied to the geometrical dimensions of the DC beam, with the beam aspect ratio being a critical factor that influences the device layer area.

The other main contributor to the overall axial stress can be the compressive stress, which can arise from the anchors restricting the thermal expansion of the DC beam. Computational simulations via COMSOL, under the assumption of fixed anchors, reveal that this compressive stress can exhibit a linear relationship, as depicted in FIG. 2C. Notably, an increase in beam width correlates with a marginal elevation in compressive stress levels. This can be attributable to the wider anchors associated with wider beams, thereby amplifying the anchor's influence and resulting in higher compressive stress. Furthermore, given that the CTE of 4H—SiC is approximately double that of silicon, the thermal compressive stress in 4H—SiC DC beam resonators is consequently twice as large as that in their silicon counterparts.

In addition to the aforementioned stress components, it is crucial to note that the axial tensile stress induced by CTE mismatch and the axial compressive stress introduced by the anchors varies along the length of the beam. Moreover, the anchors in the DC beam configuration are not rigidly fixed; they exhibit dynamic tendencies, shifting in the direction of tensile stress due to CTE disparities. Consequently, to accurately compute the net axial stress and its thermal gradient, dimension-specific constants can be incorporated for each contributing stress component.

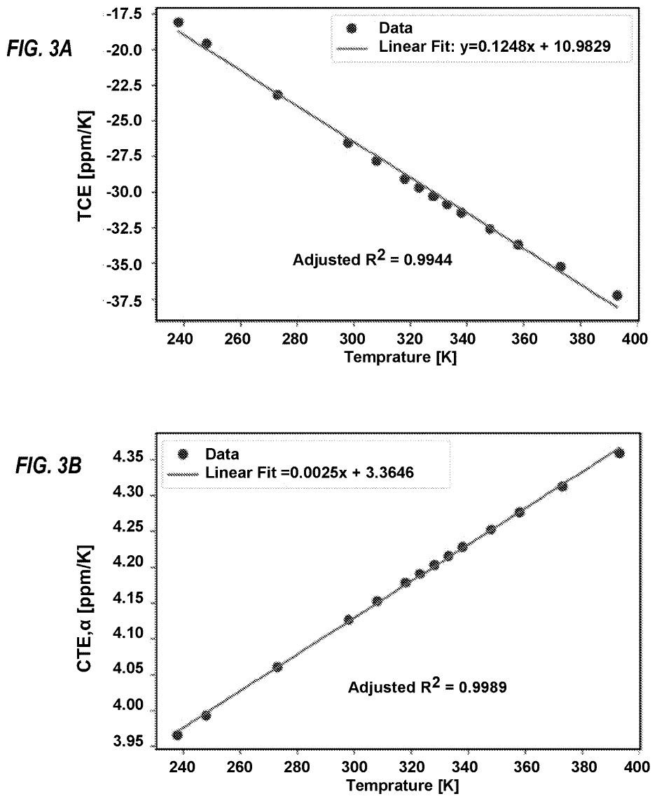

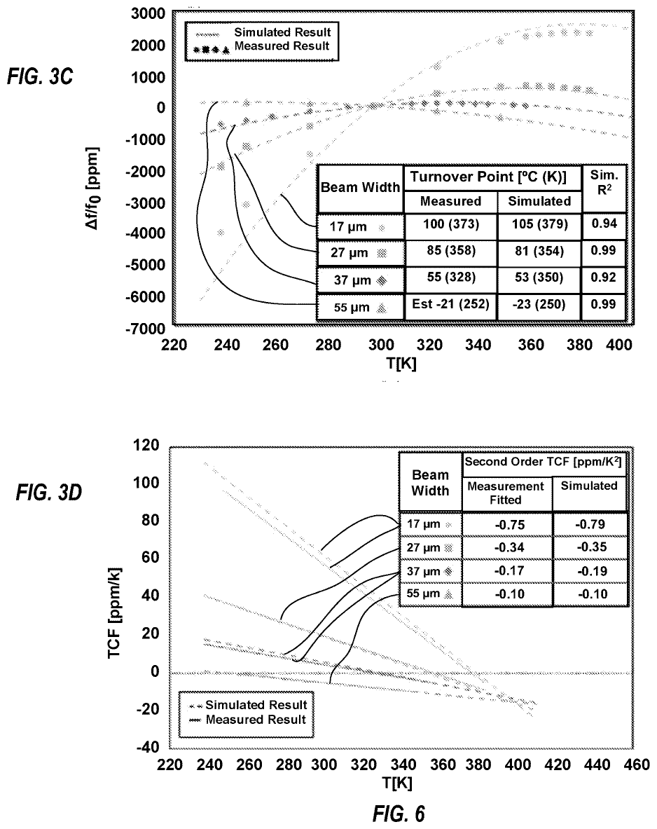

Utilizing the simplified stress-dependent TCF equation outlined in Equation 4B, along with the temperature-dependent stress change in FIGS. 2C-D, TCE, and CTE (Equations 5 and 6), a comparative analysis between simulated and empirical TCF and temperature-induced frequency shifts was conducted for a 17 μm×1100 μm DC beam. The high degree of congruence between the simulated and measured values is substantiated by adjusted R² values of 0.98 for TCF and 0.94 for frequency shifts with temperature, as depicted in FIG. 3. This affirms the model's validation. Any minor variations could potentially be attributed to other ancillary axial stress contributors such as wirebond-induced stresses, and polarization voltage-mediated material softening.

To engineer the desired TCF, encompassing TCF₁, TCF₂, and TCF turnover point, as well as to customize the overall frequency shift, it can be helpful to elucidate the interplay between the dimensions of the DC beam and those of the 4H—SiCOI system. FIG. 3 demonstrates that the frequency variation with temperature can be fitted by second-degree polynomials, resulting in a linear temperature dependence of TCF₁. Equations 5 and 6 elucidate that both TCE and CTE lack dimensional constituents and linearly correlate with temperature (FIG. 3). Given that the slope of 1/E concerning temperature approximates 6×10⁻⁵, the assumption posits 1/E remains constant over the temperature range.

In FIG. 3, the tensile stress introduced by CTE mismatch follows a decrescent parabolic trend, whereas the anchor-induced thermal stress exhibits a linear relationship with a negative slope. Consequently, the stress change rate with respect to temperature can be linearly modeled with a negative slope (a_{stress change}) and interception (b_{stress change}), depending on the DC beam dimensions. Drawing upon Equation 4B, the stress influenced TCF₁ can be formulated as:

$${TCF}_{1} = {A}_{TCF} \cdot T + {B}_{TCF} , where \qquad Equation 7$$

$${A}_{TCF} = 1.7935 \times {10}^{- 7} \cdot {( \frac{{L}_{0}}{{W}_{0}} )}^{2} \cdot {a}_{stress change} - 0.0677 ;$$

$${a}_{stress change} \leq 0$$

$$Second order TCF = {A}_{TCF}$$

$${B}_{TCF} = 1.7935 * {10}^{- 7} \cdot {( \frac{{L}_{0}}{{W}_{0}} )}^{2} \cdot {b}_{stress change} + 7.1738$$

Employing the aforementioned expression, the flexure mode DC beam TCF₁, TCF₂, and the temperature turnover point (where TCF₁ equates to zero) can be meticulously tailored by optimizing the DC beam and 4H—SiCOI system dimensions, encompassing the width-to-length ratio (L/W) of the DC beam and the thicknesses of the SiC device layer, SiO₂ BOX layer, and the Si handle layer.

As demonstrated in FIG. 3, by modulating the width of the 1100 μm long, 45 μm thick 4H—SiC DC beams within a 4H—SiCOI substrate from 17 μm to 55 μm, the (L/W) ratio calibration facilitates a shift in TCF₁ spanning from 100 ppm/K to −10 ppm/K within a 238K to 393K thermal spectrum. Moreover, based on Equation 7, the theoretical frequency deviation versus temperature in this 4H—SiCOI system can be expressed by:

$$\frac{Δ f}{{f}_{ref}} = \frac{f - {f}_{ref}}{{f}_{ref}} = \frac{{A}_{TCF}}{2} \cdot {T}^{2} + {B}_{TCF} \cdot T + C \qquad Equation 8$$

$$where C = - ( 44402 \times {A}_{TCF} + 298 \times {B}_{TCF} )$$

As delineated in FIG. 3, the adjusted R² values, which reflect the congruence of simulated frequency shifts to actual measured data points, span a range from 0.92 to 0.99. The temperature turnover point, as deduced from fitted measurements, varies from 252K to 373K with an expanded (L/W) ratio. Remarkably, this exhibits a deviation of a mere 0.06% when juxtaposed against simulations predicting the range from 250K to 379K. In addition, TCF₂, depending on the (L/W) ratio, shows values extending from −0.79 ppm/K² to −0.10 ppm/K². When paralleled with the simulated values from −0.76 ppm/K² to −0.10 ppm/², the discrepancy is only 0.08%. Given the inherent significance of TCF₂ in denoting temperature stability at the turnover point, these observations underscore the potential for customizing the temperature stabilization at the turnover point through meticulous dimensional engineering. Moreover, as the polarization voltage can also electrostatically tune the elastic property of the device material, the thermal stability of the MEMS resonator can be further tuned to achieve the desired values.

In addition, utilizing the presented methodology can allow for a reliable simulation of the temperature-induced frequency shift pertaining to the flexure mode DC beam resonator within the 4H—SiCOI system. Given a specified temperature interval, denoted as T_{low} to T_{high}, there can be two discernible scenarios: firstly, where the temperature turnover point lies external to the stipulated range (T_{low}<T_{high}≤Tₜᵤᵣₙₒᵥₑᵣ or Tₜᵤᵣₙₒᵥₑᵣ≤T_{low}<T_{high}), and secondly, where it is within this range (T_{low}<Tₜᵤᵣₙₒᵥₑᵣ<T_{high}). In the first scenario, the overall frequency shift evolves as:

$$\text{?} = \vert ( \frac{{A}_{TCF}}{2} \cdot {T}_{high}^{2} + {B}_{TCF} \cdot {T}_{high} + C ) - ( \frac{{A}_{TCF}}{2} \cdot {T}_{low}^{2} + {B}_{TCF} \cdot {T}_{low} + C ) \vert \qquad Equation 9$$

$$which simplifies to : \text{?} = Δ T \vert \frac{{A}_{TCF}}{2} \cdot ( {T}_{high} + {T}_{low} ) + {B}_{TCF} \vert$$

Incorporating the values from Equation 7 into the above, we obtain:

$$\text{?} = Δ T \vert 8.9675 \times {10}^{- 7} \cdot {( \frac{{L}_{0}}{{W}_{0}} )}^{2} [ {a}_{stress change} ( {T}_{high} + {T}_{low} ) + 2 {b}_{stress change} ] - 0.3055 ( {T}_{high} + {T}_{low} ) + 7.1 \; 738 \vert \qquad Equation 10$$

ΔT is defined by the difference between T_{high} and T_{low}. With the criteria T_{high}A_{TCF}+B_{TCF}≥0 or 0≥T_{low}A_{TCF}+B_{TCF} derived from this scenario, when the variable a_{stress change} approaches zero, the values of A_{TCF} and B_{TCF} converge towards −0.0611 and 0.0611T_{high} respectively. Consequently, the minimum overall frequency shift asymptotically approaches 0.0306ΔT².

For the second scenario where the turnover point is inside the range, the overall frequency shift can be formulated as:

$$\vert ( \frac{{A}_{TCF}}{2} \cdot {T}_{turnover}^{2} + {B}_{TCF} \cdot {T}_{turnover} + C ) - ( \frac{{A}_{TCF}}{2} \cdot {T}_{low or high}^{2} + {B}_{TCF} \cdot {T}_{low or high} + C ) \vert \qquad Equation 11$$

$$which simplifies to :$$

$$Δ = \vert ( {T}_{turnover} - {T}_{low or high} ) [ \frac{{A}_{TCF}}{2} \cdot ( {T}_{turnover} + {T}_{low or high} ) + {B}_{TCF} ] \vert$$

When the turnover point is at the arithmetic mean of T_{high} and T_{low} and the TCF₁ at the midpoint of the temperature range (Tₜᵤᵣₙₒᵥₑᵣ) equates to zero (A_{TCF}·Tₜᵤᵣₙₒᵥₑᵣ+B_{TCF}=0), the overall frequency shift can be the lowest in this scenario. Moreover, as a_{stress change} approaches zero, A_{TCF} and B_{TCF} tend towards −0.0611 and 0.0611Tₜᵤᵣₙₒᵥₑᵣ, respectively, the minimum overall frequency shift can converge asymptotically to 0.0076ΔT².

In general, given a specified temperature interval within the 4H—SiCOI material system, the lowest overall frequency shift can be infinitely close to 0.0076ΔT², predicated on the aforementioned conditions in the second scenario. To pragmatically minimize the overall frequency shift within the 4H—SiCOI material system and approach the theoretical value, several strategies can be employed: reducing the (L/W) ratio to lead A_{TCF} towards −0.0611, increasing the thickness of the device layer, or lowering the deposition temperature to shift the stress change rate closer to zero.

In extending this methodology to universal material systems, the constants for fitted TCE, CTE, 1/E, and stress change rate will vary, potentially yielding different minimum overall frequency shifts. The lowest overall frequency shift for a specified temperature range can be determined by

$$\frac{Δ {T}^{2}}{8} \vert {a}_{TCE} + {a}_{CTE} \vert .$$

Therefore, materials with lower absolute values of |a_{TCE}+a_{CTE}| will result in reduced overall frequency shifts within the given temperature range.

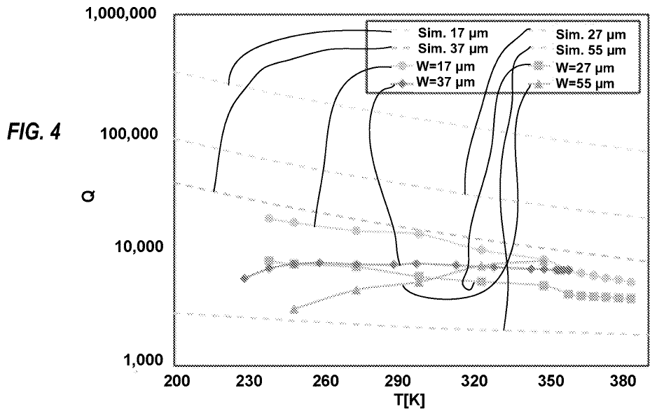

Furthermore, as delineated in FIG. 4, observations highlight a decrement in the Q-factor with rising temperatures for DC beams in 4H—SiCOI substrates exhibiting elevated (L/W) ratios, attributable primarily to the preponderance of thermoelastic damping (TED) as the energy dissipation mechanism. Conversely, with reduced ratios, beam width expansion ensues, amplifying the influence of the anchor in the energy dissipation process. Thus, in light of the decreasing Q_{TED} with temperature augmentation, coupled with Q_{anchor}, the Q-factor for the DC beams with low (L/W) ratios exhibits an uptrend with temperature elevation.

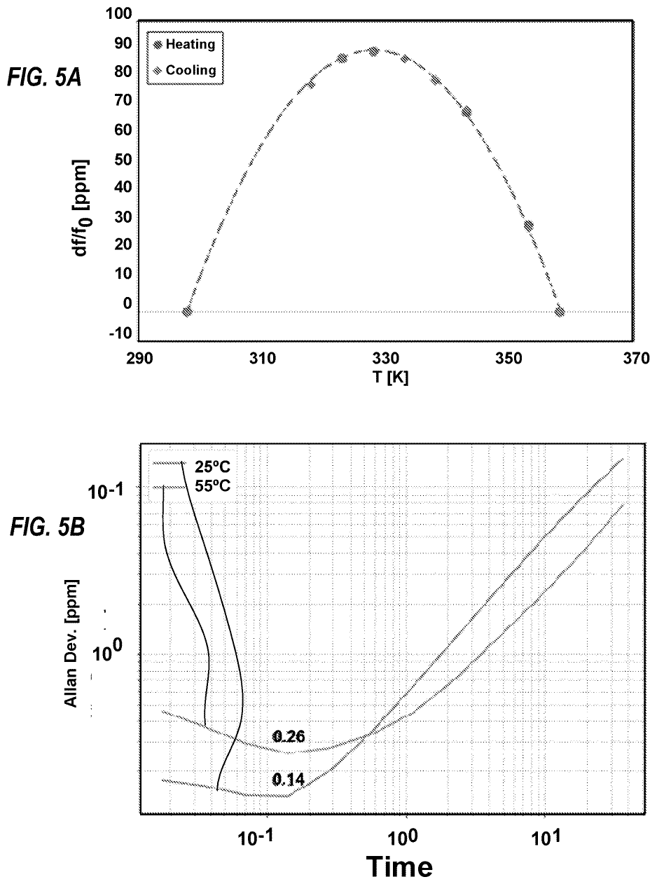

Leveraging the robust covalent bonds between the SiO₂, Si, and 4H—SiC layers in the 4H—SiCOI substrate, our 1100 μm×37 μm resonator can exhibit negligible short-term frequency hysteresis across temperature cycles, as delineated in FIG. 5Aa. This absence of hysteresis can ensure stable and reproducible performance, a significant asset in precision timekeeping endeavors. FIG. 5B further highlights the Allan Deviation (ADEV) of the resonator, which has an exceptionally low noise floor—around 0.14 ppb—at room temperature and 0.26 ppb at its temperature turnover point (55 °C), which can be mainly limited by the flicker noise of the lock-in amplifier. This can surpass the silicon-based MEMS resonator (approximately 1 ppb), which increases the clarity and resolution of the signal.

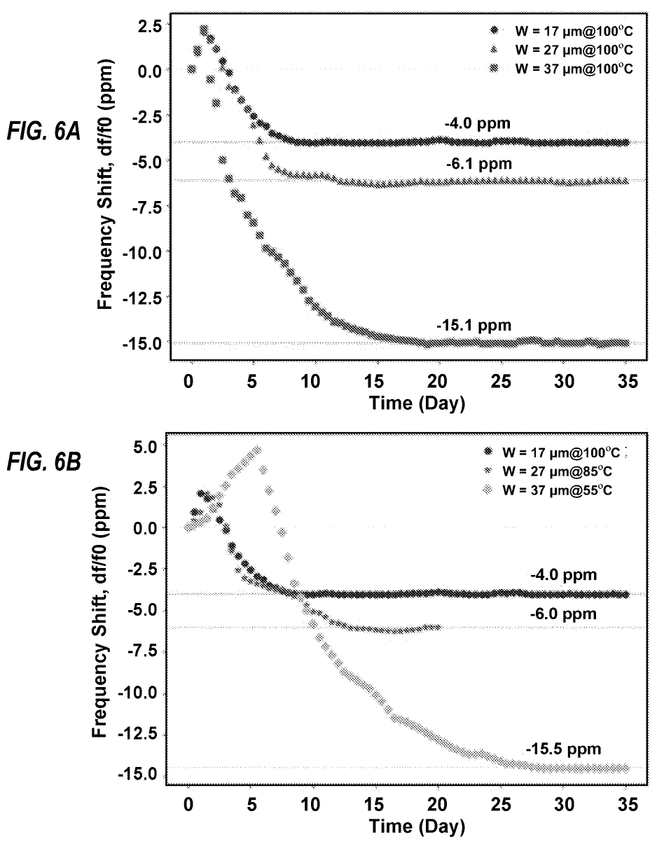

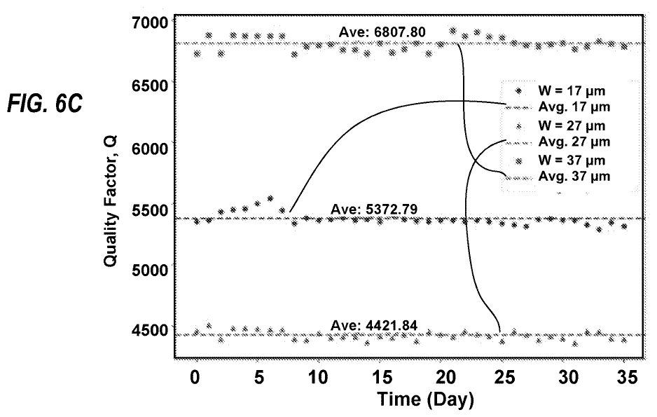

In FIG. 6A, the three exemplary DC beam resonators aged at 100 °C show preliminary burn-in drifts of −4.0 ppm, −6.1 ppm, and −15.1 ppm over approximately 8, 12, and 18 days, respectively, before reaching frequency stabilization. Subsequently, frequency fluctuations stabilize around ±0.2 ppm. In FIG. 6B, the three DC beam resonators aged at their local zero TCF points (100 °C for 17 μm, 85 °C for 27 μm, and 55 °C for 37 μm) show burn-in drifts of −4.0 ppm, −6.0 ppm, and −14.5 ppm over approximately 8, 13, and 28 days, respectively, before reaching frequency stabilization. Subsequently, frequency fluctuations stabilize at less than ±0.4 ppm. FIGS. 6A-B demonstrate that resonators achieve stable performance in less than 18 days at a pre-aged temperature of 100 °C, and that a lower aging temperature extends the burn-in period. Additionally, when operating at local zero TCF points, frequency fluctuations stabilize around ±0.4 ppm at 55 °C, with higher temperatures reducing fluctuations to ±0.2 ppm, primarily due to oven temperature instability of ±1 °C. In FIG. 6C, at 100 °C, the quality factor changes of all three resonators are stable around their average value with fluctuations of about 2%.

These compelling attributes of short and long term stability investigations collectively position the exemplary resonators disclosed herein as an extraordinarily reliable, efficient, and versatile instrument for advanced precision timekeeping applications.

### Materials and Methods

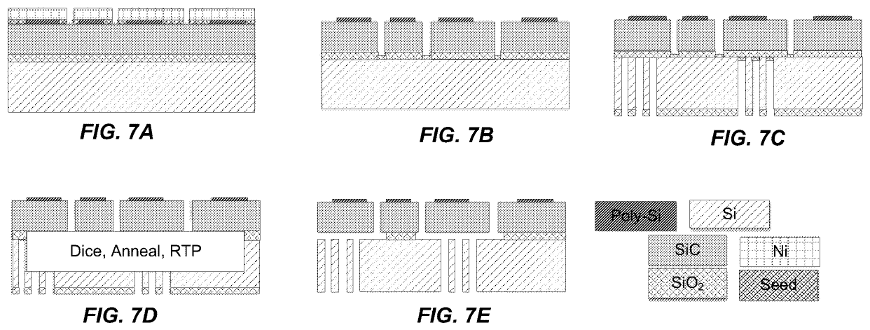

The exemplary 4H—SiCOI substrate comprises 45 μm thick 4H—SiC device layer, 3 μm thick buried SiO2 layer, and a 500 μm thick Si handle layer as shown in FIG. 1. FIG. 7 outlines the 4H—SiCOI substrate's low-temperature wafer-level fabrication process. This method has garnered widespread validation across an extensive spectrum of monocrystalline 4H—SiC resonators. Initially, a 4H—SiC wafer was wet oxidized and bonded onto a silicon substrate with the aid of TEOS SiO₂ as an intermediate bonding agent at 700 °C, followed by subsequent wafer grinding and polishing, which generated the 100 mm 4H—SiCOI wafer. Then, the in-situ doped polysilicon forms electrode pads on the SiC surface (FIG. 7A). A Cr/Au seed layer is used to create an electroplated Ni-hard mask for 4H—SiC deep reactive-ion etching (DRIE) (FIG. 7B). For backside processing, the wafer undergoes PECVD SiO₂ patterning followed by standard Bosch-process etching in the Si handle layer (FIG. 7C). The die-level annealing at 1100 °C is performed for oxide densification and the formation of ohmic contacts between polysilicon and SiC (FIG. 7D), followed by the HF releasing.

The temperature characterizations are done in the Ideal Aerosmith 1291BL temperature chamber, with a temperature stability of ±1 °C, while the resonator is under 7.5×10⁻⁷ Torr vacuum with the TPS-Compact vacuum pump from VARIAN. The hysteresis characterizations are done by applying temperature cycles to the resonator and monitoring its resonance frequency and Q. For this purpose, the temperature is gradually ramped up from 25 °C to 85 °C and then ramped down back to 25 °C. A temperature stabilization time of 3 hours is considered between consecutive temperature changes prior to frequency and Q measurements. The long-term stability characterization of the 1100 μm×37 μm beam resonator lasted for 37 days with 25 data points collected per time and twice per day, where the standard deviation for each time's data is less than 0.1 ppm. The short-term stability, ADEV characterization is done with HF2LI 50 MHz lock-in amplifier from Zurich Instruments, at the resonator's temperature turnover point.

Thermal characterizations are conducted in an Ideal Aerosmith 1291BL temperature chamber, with a temperature stability of ±1 °C. The resonators are subjected to a high vacuum of 7.5×10⁻⁷ Torr, facilitated by a TPS-Compact vacuum pump from VARIAN. Hysteresis analyses were performed through cyclic thermal exposure of the resonator, systematically monitoring its resonant frequency and Q-factor. The chamber temperature was incrementally elevated from 25 °C to 85 °C before reverting to 25 °C, with an interlude of 3 hours allocated for thermal stabilization preceding each frequency and Q-factor assessment. Long-term stability evaluations spanned 37 days, with semi-daily data acquisition involving 25 data points per epoch; the standard deviation among these points remained below 0.1 ppm. For short-term stability—specifically, the Allan Deviation (ADEV)—measurements were executed using an HF2LI 50 MHz lock-in amplifier from Zurich Instruments, strategically targeting the resonator's temperature turnover point.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

Furthermore, the purpose of the foregoing Abstract is to enable the United States Patent and Trademark Office and the public generally, and especially including the practitioners in the art who are not familiar with patent and legal terms or phraseology, to determine quickly from a cursory inspection the nature and essence of the technical disclosure of the application. The Abstract is neither intended to define the claims of the application, nor is it intended to be limiting to the scope of the claims in any way.

1.-11. (canceled)

12. A method of manufacturing a micro-electromechanical (MEMS) resonator having one or more desired properties comprising:
selecting one or more dimensions and/or materials of the MEMS resonator based on one or more desired properties; and
providing the MEMS resonator with one or more of the dimensions and/or one or more of the materials;
wherein one or more of the desired properties is selected from a group consisting of a temperature coefficient of frequency (TCF), a temperature turnover point, and a frequency shift.

13. The method of claim 12, wherein one or more dimensions of the MEMS resonator is selected from a group consisting of a length of the resonator, a width of the resonator, an aspect ratio of the resonator, a thickness of the resonator, a radius of the resonator, a length of one or more anchors of the resonator, a width of one or more of the anchors, an aspect ratio of one or more of the anchors, and a thickness of one or more of the anchors.

14. The method of claim 12 further comprising:
actuating and sensing vibration of the MEMS resonator using capacitive transducers having airgaps.

15. The method of claim 12, wherein:
one of the desired properties is the TCF; and
the TCF comprises a range of desired TCFs for the MEMS resonator over a predetermined temperature range.

16. The method of claim 12, wherein the desired property is a TCF with a positive value.

17. The method of claim 15, wherein the predetermined temperature range is from about 200K to about 500K.

18. The method of claim 12, wherein the providing comprises inducing axial stress in the MEMS resonator by leveraging a coefficient of thermal expansion (CTE) mismatch between a material of the MEMS resonator and at least one layer positioned beneath the MEMS resonator.

19. The method of claim 18, wherein;
the material of the MEMS resonator comprises silicon carbide; and
at least one of the layers positioned beneath the MEMS resonator comprises silicon.

20. The method of claim 18 further comprising:
bonding at least one of the layers positioned beneath the MEMS resonator the MEMS resonator via a silicon dioxide laver;
wherein the MEMS resonator is a silicon carbide resonator.

21. The method of claim 12, wherein the MEMS resonator is selected from a group consisting of a beam resonator, a ring resonator, a frame resonator, a rectangular resonator, a flexural mode resonator, a torsional resonator, and an extensional mode resonator.

22. The method of claim 12, wherein:
one of the desired properties is the temperature turnover point; and
one or more of the dimensions of the MEMS resonator is selected based on the temperature turnover point.

23. The method of claim 22, wherein the temperature turnover point is between 200K and 500K.

24. A micro-electromechanical (MEMS) resonator manufactured by the method of claim 12, wherein:
the MEMS resonator is made in silicon-carbide having a positive temperature coefficient of frequency (TCF) over a portion of a temperature range from 200K to about 500K; and
vibration of the MEMS resonator is actuated and sensed using capacitive transducers having airgaps.

25. The MEMS resonator of claim 24, wherein the MEMS resonator has one or more dimensions selected to achieve the positive TCF.

26. The MEMS of claim 24, wherein the MEMS resonator is one of a beam resonator, a ring resonator, a frame resonator, a rectangular resonator, a flexural mode resonator, a torsional resonator, or an extensional mode resonator.

27. The MEMS of claim 24, wherein the MEMS resonator has a temperature turnover point of TCF between 200K and 500K.

28. The method of claim 12, wherein the providing comprises manipulating the TCF of the MEMS resonator through control of MEMS resonator structural stress.

29. The method of claim 12, wherein the providing comprises controlling tensile and compressive stress-changing rates in the MEMS resonator when exposed to temperature variations, thereby manipulating one or more of the desired properties to achieve a desired value.

30. The method of claim 12, wherein the providing comprises:
disposing the MEMS resonator on a substrate and between two fixed anchors, one each located on opposing ends of the MEMS resonator;
exposing the MEMS resonator, substrate, and fixed anchors to temperature variations;
inducing, in the MEMS resonator, a tensile stress having a tensile stress-changing rate due to the temperature variations by leveraging a coefficient of thermal expansion (CTE) mismatch between a material of the MEMS resonator and at least one layer positioned beneath the MEMS resonator; and
inducing, in the MEMS resonator, a compressive stress having a compressive stress-changing rate due to the temperature variations when the MEMS resonator undergoes volume changes while remaining between the fixed anchors.

31. The method of claim 30, wherein the providing further comprises controlling the tensile and compressive stress-changing rates, thereby manipulating one or more of the desired properties to achieve a desired value.
